(19) United States
(12) Patent Application Publication
(10) Pub. No.: US 2004/0146169 A1
(43) Pub. Date: Jul. 29, 2004

(54) Digital music player

(75) Inventor: Tonny Chen, Chang-Hua (TW)

Correspondence Address: BRUCE H. TROXELL, SUITE 1404, 5205 LEESBURG PIKE, FALLS CHURCH, VA, 22041, US

(73) Assignee: E-Lead Electronic Co., Ltd.

(21) Appl. No.: 10/353,045

(22) Filed: Jan. 29, 2003

(51) Int. Cl. H04B 3/00; G06F 17/00; H03G 3/00

(52) U.S. Cl. 381/77; 381/104; 700/94

(57) ABSTRACT

A digital music player and particularly a music player capable of coupling with an audio system or a radio to broadcast digital music without altering the original design of FM, AM or cassette tape playing functions, and reading digital music data from different storage devices through a storage device interface includes a storage device connector, a storage device interface chip, a digital music decoding unit, an audio signal output unit and a power supply unit. The digital music player allows users to read digital music data from different storage devices and transmit by radio signals to the audio system or radio for receiving and broadcasting digital music in addition to the FM, AM or cassette tape playing functions.

### BACKGROUND OF THE INVENTION

1. Field of the Invention

The invention relates to a digital music player and particularly a music player that allows users to read digital music data from different storage devices and transmit by radio signals to an audio system or radio for receiving and broadcasting digital music in addition to FM, AM or cassette tape playing functions.

2. Description of the Prior Art

Refer to FIG. 1 for the structure of a conventional digital music player 1. It mainly consists of a memory unit 11, a digital music broadcasting unit 12, an earphone jack 13 and an earphone 14. The memory unit 11 provides recording digital music data. It may be a flash memory card or a memory card (such as CF, MD, SD, MMC, SM, MS, etc.). As the capacity of the memory unit 11 is limited (the flash memory card or memory card generally has a capacity of 256 MB to 512 MB), users have to update (or replace) the memory unit 11 (memory card) frequently. It is not convenient to use. Presently, there are portable data storage devices that have huge data storage capacities. They are mostly made in the form of a portable disk with a USB interface. Their capacities may be up to one billion bytes (1 GB). The USB interface is universally adaptable to various types of information products. Hence if the memory unit II of the conventional digital music player 1 is equipped with the capability of reading the portable disk, the performance of digital music application can be greatly enhanced, and users can be freed from the trouble of updating data frequently.

Moreover, listening digital music is not limited to houses. Car also is a location where digital music is played frequently. However, the present car stereo systems usually do not offer digital music playing function. This is a need still to be fulfilled.

### SUMMARY OF THE INVENTION

In view of the aforesaid disadvantages, the invention aims at providing a novel digital music player that mainly includes a storage device connector, a storage device interface chip, a digital music decoding unit, an audio signal output unit and a power supply unit. The digital music player of the invention can read digital music data stored in different digital storage devices, and transmit by radio signals to an audio system or radio that has AM, FM or cassette tape playing functions for receiving and broadcasting digital music.

The primary object of the invention is to provide a digital music player and particularly a music player that allows users to read digital music data from different storage devices and transmit by radio signals to an audio system or radio that has FM, AM or cassette tape playing functions for receiving and broadcasting digital music.

The foregoing, as well as additional objects, features and advantages of the invention will be more readily apparent from the following detailed description, which proceeds with reference to the accompanying drawings.

### BRIEF DESCRIPTION OF THE DRAWINGS

FIG. 1 is a schematic block diagram of a conventional digital music player.

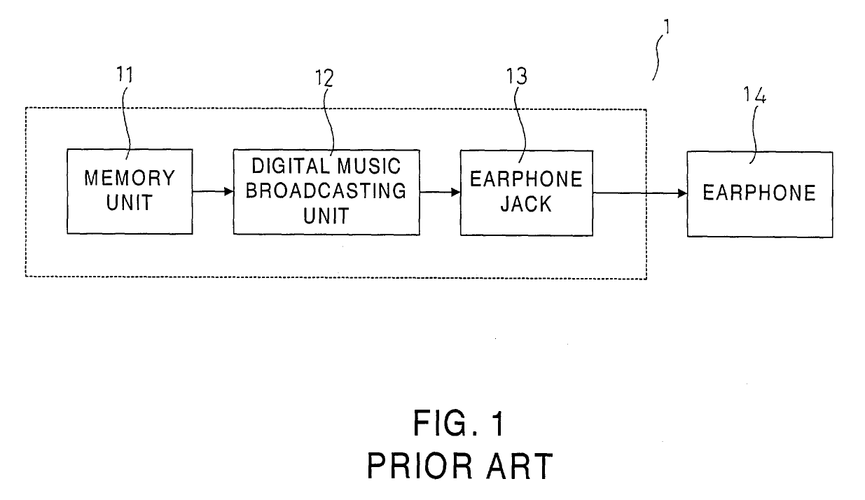

FIG. 2 is a block diagram of a first embodiment of the digital music player of the invention.

FIG. 3 is a block diagram of a second embodiment of the digital music player of the invention.

FIG. 4 is a block diagram of a third embodiment of the digital music player of the invention.

FIG. 5 is a block diagram of a fourth embodiment of the digital music player of the invention.

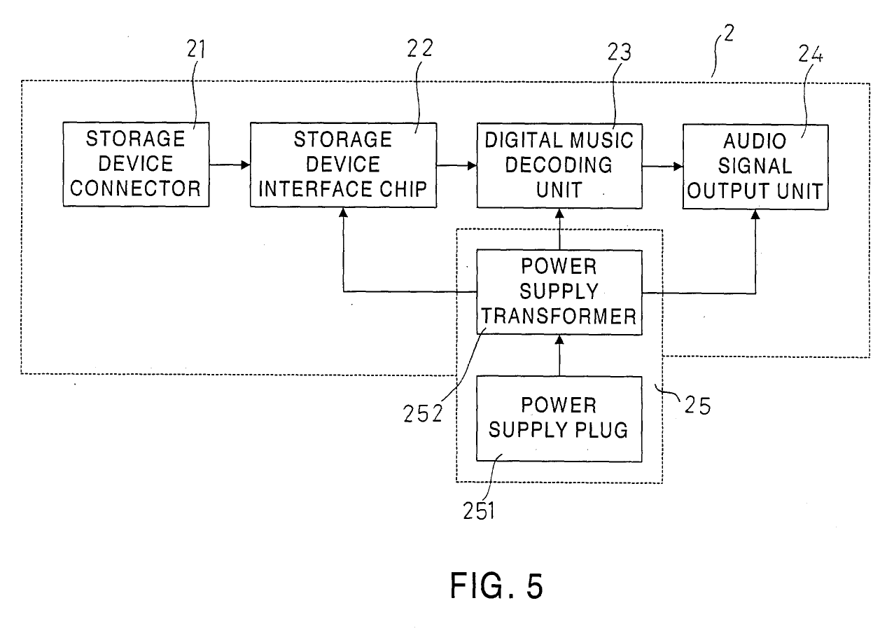

### DESCRIPTION OF THE PREFERRED EMBODIMENTS

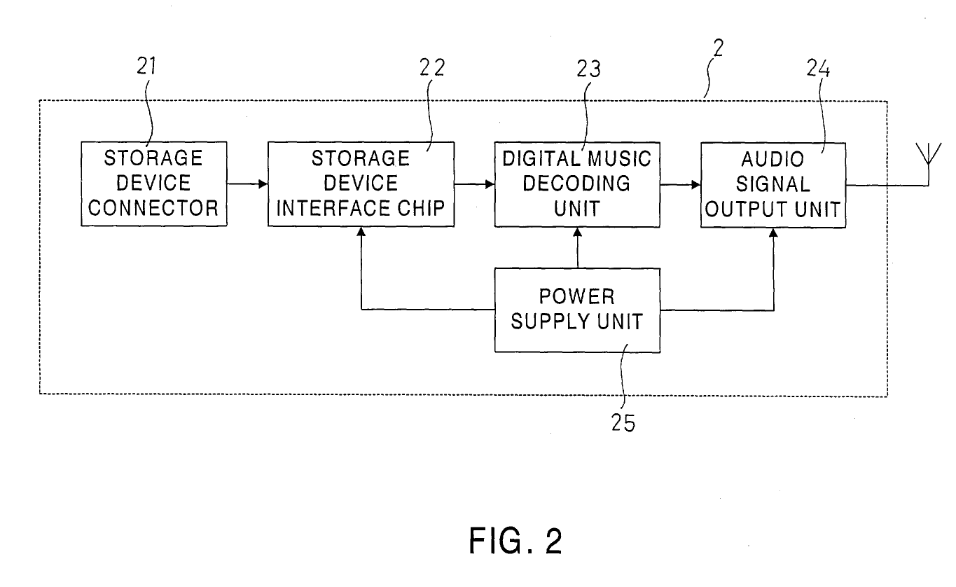

Refer to FIG. 2 for a first embodiment of the invention. The digital music player 2 of the invention mainly includes a storage device connector 21, a storage device interface chip 22, a digital music decoding unit 23, an audio signal output unit 24 and a power supply unit 25.

The storage device connector 21 is a connector for connecting to a storage device, such as a memory card slot, a USB connector, etc. The storage device may be a portable disk or a memory card with a USB interface (such as CF, MD, SD, MMC, SM, MS, etc.).

The storage device interface chip 22 is for retrieving data stored in the storage device.

The digital music decoding unit 23 is for transforming and enabling the digital music data retrieved from the storage device to music signals for broadcasting.

The audio signal output unit 24 modulates the data transferred from the digital music decoding unit to radio signals for emission. The radio signals are received by an audio system or radio for broadcasting. The output unit may be a FM or AM emission circuit.

The power supply unit 25 provides electric power required by the digital music player 2. The electric power source of the power supply unit 25 may be batteries.

By means of the elements and construction set forth above, users may plug a digital storage device to the digital storage device connector of the digital music player 2. Through the storage device interface chip 22, the digital music data stored in the digital storage device may be retrieved and transferred to the digital music decoding unit 23. The digital music decoding unit 23 decodes the data and the audio signal output unit 24 modulates the data to radio signals for transmitting to an audio system or radio which receives and broadcasts the digital music.

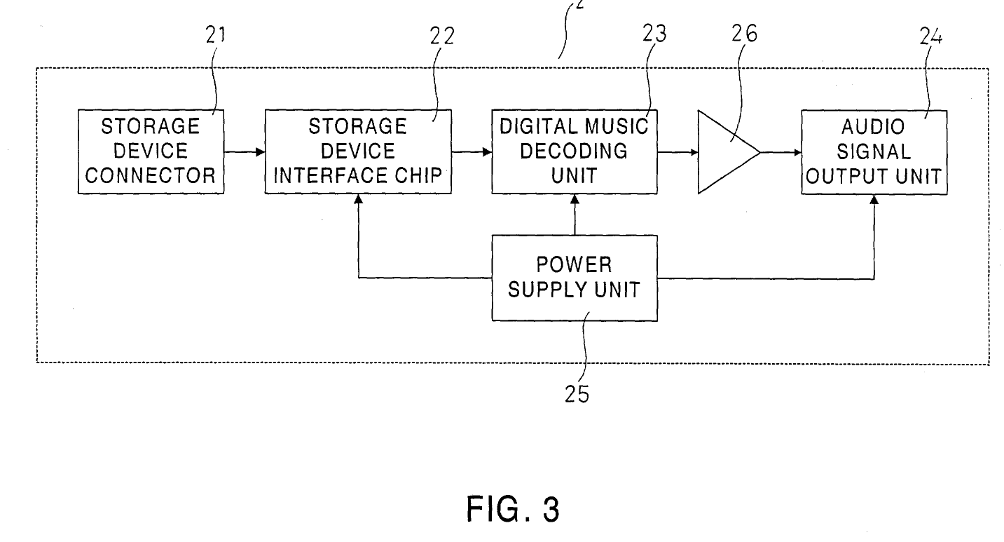

Refer to FIG. 3 for a second embodiment of the invention. In this embodiment an amplifier 26 is added to increase the gain of the audio signal output by the digital music decoding unit 23.

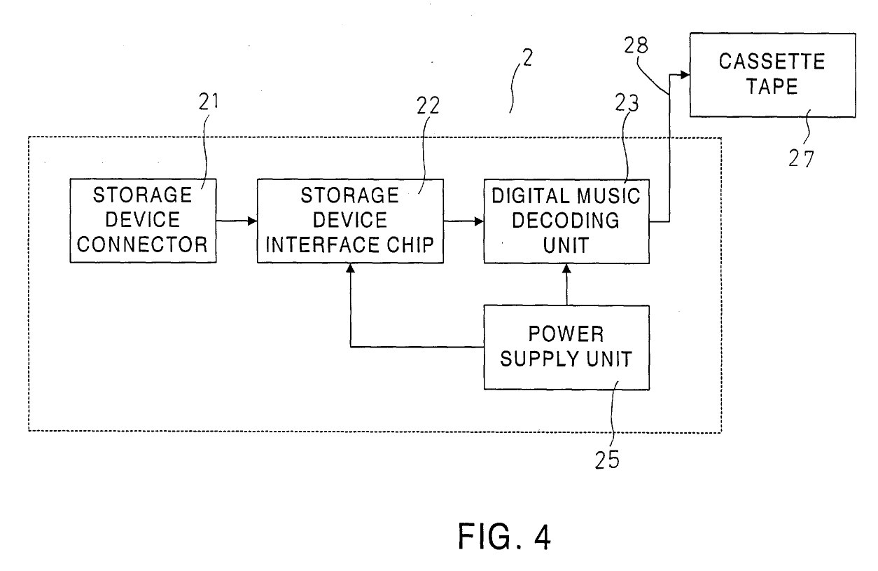

Refer to FIG. 4 for a third embodiment of the invention. In order to expand the application of the invention, the audio signal output unit 24 may be a cassette tape 27 and an extension line 28 which connects to the cassette tape 27 and the digital music player 2.

An user may dispose the cassette tape 27 in the cassette tape slot of an audio system or radio. The digital music player 2 transfers the digital music signals from the cassette tape 27 to the magnetic head of the audio system or radio for broadcasting the digital music (the digital music reading operation of the digital music player is same as the first embodiment, and the cassette tape is a medium known in the art that forms no part of the invention, thus details are omitted).

Refer to FIG. 4 for a fourth embodiment of the invention. In order to expand the power supply selection, the power supply unit 25 may include:

a power supply plug 251 for connecting to an external power supply to provide electric power to the digital music player 2, such as a household power supply plug, a car cigarette lighter, or the like; and

a power supply transformer 252 for transforming the electric power input from the power supply plug 251 to the operation voltage of the digital music player 2.

By means of the aforesaid elements, the digital music player of the invention may use the power supply of the house or car.

In summary, the invention can retrieve digital music data from storage device interfaces and transmit by radio fashion to enable audio systems and radios that have FM, AM or cassette tape playing functions to receive and broadcast digital music.

While the preferred embodiments of the invention have been set forth for the purpose of disclosure, modifications of the disclosed embodiments of the invention as well as other embodiment thereof may occur to those skilled in the art. Accordingly, the appended claims are intended to cover all embodiments which do not depart from the spirit and scope of the invention.

I claim:

1. A digital music player for reading data from a storage device of a great capacity and allowing an audio system without digital music playing function to broadcast digital music, comprising: a storage device connector, a storage device interface chip, a digital music decoding unit, an audio signal output unit and a power supply unit, wherein:
the storage device connector is a connector for connecting to the storage device;
the storage device interface chip is for reading data stored in the storage device;
the digital music decoding unit is for transforming and enabling the digital music data read from the storage device to music signals for broadcasting;
the audio signal output unit modulates the data transferred from the digital music decoding unit to radio signals for emission, the radio signals being be received by an audio system or a radio for broadcasting; and
the power supply unit provides electric power required by the digital music player.

2. The digital music player of claim 1, wherein the audio signal output unit is a frequency modulation circuit.

3. The digital music player of claim 1, wherein the audio signal output unit is an amplitude modulation circuit.

4. The digital music player of claim 1 further having an amplifier to increase the gain of the music signals output by the digital music decoding unit.

5. The digital music player of claim 1, wherein the electric power source of the power supply unit is a battery.

6. The digital music player of claim 1, wherein the power supply unit further includes:
a power supply plug for connecting to an external power supply to provide electric power for the digital music player; and
a power supply transformer for transforming the electric power input from the power supply plug to an operation voltage of the digital music player.

7. The digital music player of claim 1, wherein the audio signal output unit is a cassette tape and an extension line which connects to the cassette tape and the digital music player;
wherein the cassette tape is allowed to be disposed in a cassette tape slot of the audio system or a radio to transfer digital music signals from the cassette tape to the magnetic head of the audio system or the radio for broadcasting the digital music.

8. The digital music player of claim 1, wherein the storage device connector is an insert slot of a digital memory card, the memory card being selected from the group consisting of CF, MD, SD, MMC, SM and MS.

9. The digital music player of claim 1, wherein the storage device connector is an insert slot of a USB interface.
